(19) United States
(12) Patent Application Publication
(10) Pub. No.: US 2026/0172067 A1
(43) Pub. Date: Jun. 18, 2026

(54) MULTI-CONNECTIVITY AUTOMATIC GAIN CONTROL

(71) Applicant: QUALCOMM Incorporated, San Diego, CA (US)

(72) Inventors: Saranyan NAGARAJAN, Hyderabad (IN); Raveesh JUNEJA, Hyderabad (IN); Murali MENON, Acton, MA (US)

(21) Appl. No.: 18/986,082

(22) Filed: Dec. 18, 2024

(51) Int. Cl. H04B 1/40; H04B 17/318

(52) U.S. Cl. CPC H04B 1/40; H04B 17/328

(57) ABSTRACT

Certain aspects of the present disclosure provide techniques for multi-connectivity automatic gain control. An example method of wireless communications includes receiving, via a receive path, signaling comprising a first signal and a second signal, wherein the receive path comprises one or more components. The method further includes adjusting a set of gains applied to the one or more components based at least in part on one or more first metrics associated with the first signal and one or more second metrics associated with the second signal.

### INTRODUCTION

### Field of the Disclosure

Aspects of the present disclosure relate to automatic gain control, and more particularly, to automatic gain control for multi-connectivity communications.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate radio frequency (RF) signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with an RF transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry can still consume a non-trivial amount of power to perform certain operations, such as automatic gain control. Accordingly, there is a continuous desire to improve the technical performance of RF circuitry, such as automatic gain control.

### SUMMARY

Certain aspects provide an apparatus configured for wireless communications. The apparatus includes a receive path configured to receive signaling comprising a first signal associated with a first radio access technology and a second signal associated with a second radio access technology, wherein the receive path comprises a first receive chain and a second receive chain, wherein the first receive chain comprises a first set of components, and wherein the second receive chain comprises a second set of components. The apparatus further includes one or more processors coupled to the receive path, the one or more processors being configured to cause the apparatus to adjust a set of gains applied to the first set of components and the second set of components based at least in part on a comparison between one or more first metrics associated with the first signal and one or more second metrics associated with the second signal.

Certain aspects provide a radio frequency (RF) circuit configured for wireless communications. The RF circuit includes a transceiver comprising a receive path configured to receive, in a multi-connectivity mode, signaling comprising a first signal associated with a first radio access technology and a second signal associated with a second radio access technology, wherein the receive path comprises a first receive chain and a second receive chain, wherein the first receive chain comprises a first set of components including a first set of mixers, and wherein the second receive chain comprises a second set of components including a second set of mixers. The transceiver further comprises a frequency synthesizer coupled to the first set of mixers and the second set of mixers, wherein the frequency synthesizer is configured to feed one or more local oscillator signals to the first set of mixers and the second set of mixers. The RF circuit further includes one or more processors coupled to the receive path, the one or more processors being configured to adjust a set of gains applied to the first set of components and the second set of components based at least in part on a comparison between one or more first signal strengths associated with the first signal and one or more second signal strengths associated with the second signal.

Certain aspects provide a method of wireless communications. The method includes receiving, via a receive path comprising a first receive chain and a second receive chain, signaling comprising a first signal associated with a first radio access technology and a second signal associated with a second radio access technology, wherein the first receive chain comprises a first set of components, and wherein the second receive chain comprises a second set of components. The method further includes adjusting a set of gains applied to the first set of components and the second set of components based at least in part a comparison between on one or more first metrics associated with the first signal and one or more second metrics associated with the second signal.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 depicts an example wireless communications system.

FIG. 2 depicts an example wireless communications device communicating with another device.

FIG. 3 depicts an example receiver architecture that employs multi-connectivity automatic gain control (AGC).

FIG. 4 depicts example operations for multi-connectivity AGC.

FIG. 5 depicts an example method for wireless communications by an apparatus.

FIG. 6 depicts a communications device that may include various components configured to perform operations for the techniques disclosed herein.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatuses, methods, processing systems, and computer-readable mediums for multi-connectivity automatic gain control (AGC). AGC refers to an operation where a receiver may automatically control the gain applied to a received signal such that the dynamic amplitude range of the received signal matches the maximum allowable input level of a quantizer (e.g., a voltage input range of an analog-to-digital converter (ADC)). AGC effectively normalizes the amplitude variance of the received signal to the voltage input range of the ADC. AGC allows the ADC to digitize the received signal without clipping certain amplitudes, such as a peak amplitude or a minimum amplitude. For example, an ADC may clip an input signal when the amplitude of the input signal exceeds the maximum allowable input level or is below the minimum input level of the ADC. Note that AGC operations may adjust the gain applied to components of a receive path based on additional or alternative criteria, such as a receiver sensitivity (e.g., a minimum signal strength that a receiver can detect) and/or a maximum input level (e.g., a maximum signal strength that the receiver can handle).

Certain wireless communication systems (e.g., Evolved Universal Terrestrial Radio Access (E-UTRA) systems, 5G New Radio (NR) systems, and/or future wireless communication systems) may allow a wireless communications device (e.g., a user equipment (UE)) to communicate with multiple base stations. Multi-connectivity may refer to a state where a UE is communicating with multiple base stations or radio units. Dual-connectivity may refer to a state where the UE is communicating with two base stations (or radio units). In certain cases, the UE may communicate with multiple base stations using different radio access technologies (RATs), such as E-UTRA and 5G NR dual connectivity (EN-DC). To communicate with multiple base stations, the UE may have a transceiver that uses a receive path per connection with a base station. As an example, for EN-DC, the UE transceiver may use a first receive path to receive signaling transmitted by a first base station (e.g., an evolved Node B (eNB)) and a second receive path to receive signaling transmitted by a second base station (e.g., a next generation Node B (gNB)).

Technical problems for multi-connectivity include, for example, effective AGC for multi-connectivity communications via multiple RATs, such as EN-DC. For multi-connectivity communications (such as EN-DC), the AGC may be performed separately for each receive path used to receive the signaling transmitted by a different base station. As an example, a UE may determine a first gain state (e.g., a set of gains applied to one or more components in a receive path) for the first receive path based on the signaling received via the first receive path, and the UE may determine a second gain state for the second receive path based on the signaling received via the second receive path. The first gain state may be different from the second gain state. The separate AGC operations may be performed in part due to the different reference signals being used for the different RATs. As an example, the AGC associated with E-UTRA may depend on a cell-specific reference signal (CRS), and the AGC associated with 5G NR may depend on a synchronization signal (e.g., a synchronization signal/physical broadcast channel block (SSB)) and/or a tracking reference signal. Accordingly, a UE that employs a receive path per connection with a base station may use a non-trivial amount of power consumption, for example, in part due to the separate AGC operations.

Certain aspects described herein may overcome the aforementioned technical problem(s), for example, by providing multi-connectivity AGC that uses a single receive path, which may enable reduced power consumption for multi-connectivity communications. As used herein, multi-connectivity AGC may refer to a form of AGC that determines a gain state for the receive path based on multiple received signals associated with different RATs. The multi-connectivity AGC may converge certain metrics associated with different RATs to automatically control the gain state applied to certain component(s) of the receive path. A wireless communications device (such as UE) may determine a common metric (e.g., a common signal strength) based on multiple received signals associated with the different RATs, and the wireless communications device may determine the gain state applied to the component(s) of the receive path based on the common metric. As an example, the wireless communications device may determine a first signal strength based on received signals associated with a first RAT, and the wireless communications device may determine a second signal strength based on received signals associated with a second RAT. The wireless communications device may determine a common signal strength based on the first signal strength and the second signal strength, and the wireless communications device may determine a gain state applied to the component(s) of the receive path based on the common signal strength.

Certain techniques for multi-connectivity AGC described herein may provide various beneficial technical effects and/or advantages. The techniques for multi-connectivity AGC may enable improved wireless communication performance, such as reduced power consumption and/or lower complexity. The reduced power consumption may be attributable to the multi-connectivity AGC allowing multi-connectivity communications to be performed via a single receive path. In certain cases, the multi-connectivity AGC described herein may enable a low-power, low-cost device (such as an Internet of Things (IoT) device, a low cost cellular phone, etc.) to perform multi-connectivity communications. Accordingly, multi-connectivity AGC may allow a receiver architecture that is capable of receiving multi-connectivity signaling via a single receive path with reduced power consumption and/or lower complexity.

### Example Wireless Communications System

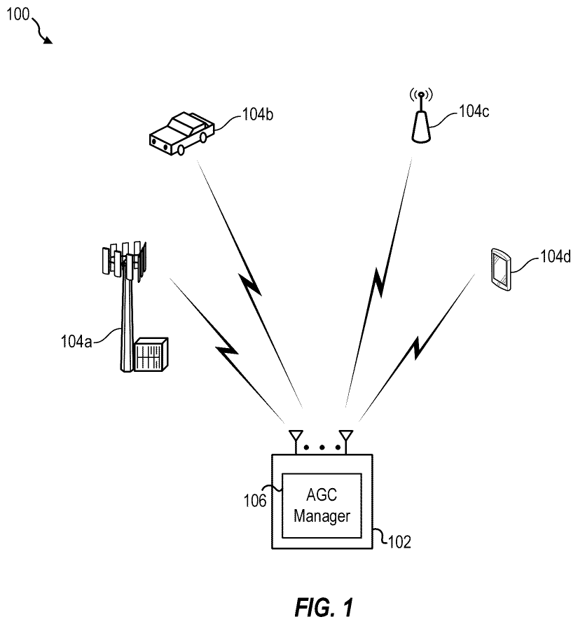

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), D2D communications, etc.

The first wireless device 102 may include any of various wireless communications devices including a user equipment (UE), a base station, a wireless station, an access point, customer-premises equipment (CPE), etc. In certain aspects, the first wireless device 102 includes an automatic gain control (AGC) manager 106 that performs multi-connectivity AGC, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

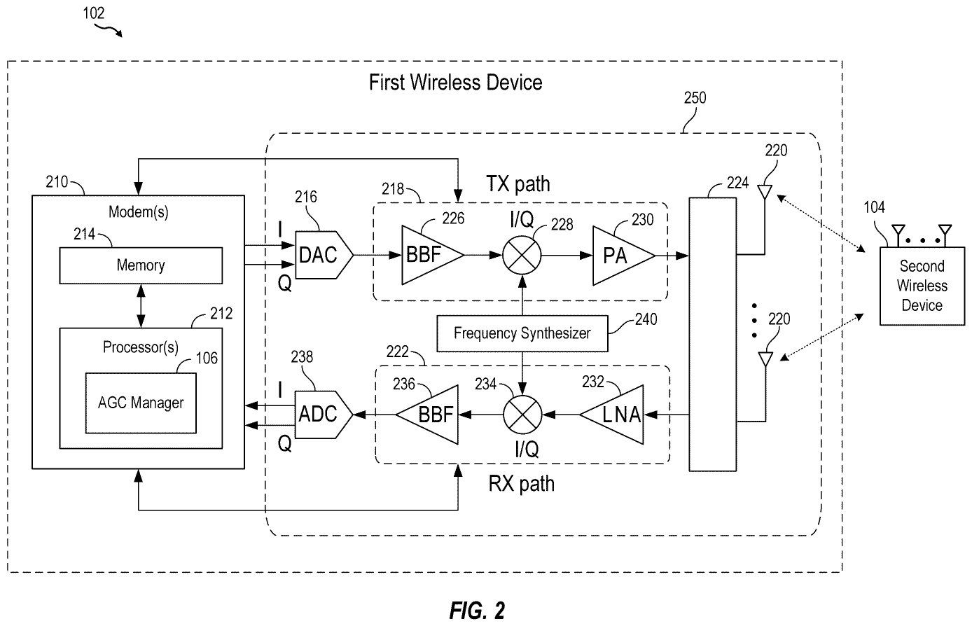

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA, 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”). In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”). In some cases, the processor 212 may implement and/or include the AGC manager 106 of FIG. 1. In certain aspects, the processor 212 and/or the memory 214 may be implemented external or otherwise separate from the modem 210.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, AGC (e.g., the AGC manager 106 configured to perform multi-connectivity AGC as further described herein), a coder, a decoder, a multiplexer, and/or a demultiplexer (not shown). In some aspects, the AGC manager 160 as described may be included in the transceiver 250 (e.g., with similar memory/processor).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a balun, a transformer, an antenna tuner, a switch, a duplexer, a diplexer, a multiplexer, and or like. As an example, the modem 210 may output digital in-phase (I) and/or quadrature (Q) baseband signals representative of the respective symbols to the DAC 216. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 or a portion thereof is also omitted from the single chip.

Receiving I or Q baseband analog signals from the DAC 216, the TX path 218 may include a baseband filter (BBF) 226, a mixer 228 (which may include one or several mixers), and a power amplifier (PA) 230. The BBF 226 filters the baseband signals received from the DAC 216, and the mixer 228 mixes the filtered baseband signals with a transmit local oscillator (LO) signal to convert the baseband signal to a different frequency (e.g., upconvert from a baseband frequency to a radio frequency). In some aspects, the frequency conversion process produces the sum and difference frequencies between the LO frequency and the frequencies of the baseband signal. The sum and difference frequencies are referred to as the beat frequencies. Some beat frequencies are in the RF range, such that the signals output by the mixer 228 are typically RF signals, which may be amplified by the PA 230 before transmission by the antennas 220. The antennas 220 may emit RF signals, which may be received at the second wireless device 104. While one mixer 228 is illustrated, several mixers may be used to upconvert the filtered baseband signals to one or more intermediate frequencies and to thereafter upconvert the intermediate frequency signals to a frequency for transmission.

The RX path 222 may include a low noise amplifier (LNA) 232, a mixer 234 (which may include one or several mixers), and a baseband filter (BBF) 236. RF signals received via the antennas 220 (e.g., from the second wireless device 104) may be amplified by the LNA 232, and the mixer 234 mixes the amplified RF signals with a receive local oscillator (LO) signal to convert the RF signal to a baseband frequency (e.g., downconvert the RF signal to the baseband frequency). The baseband signals output by the mixer 234 may be filtered by the BBF 236 before being converted by an analog-to-digital converter (ADC) 238 to digital I or Q signals for digital signal processing. The modem 210 may receive the digital I or Q signals and further process the digital signals, for example, demodulating the digital signals into information.

Certain transceivers may employ frequency synthesizers with a voltage-controlled oscillator (VCO) to generate a stable, tunable LO frequency with a particular tuning range. Thus, the transmit LO frequency may be produced by a frequency synthesizer 240, which may be buffered or amplified by an amplifier (not shown) before being mixed with the baseband signals in the mixer 228. Similarly, the receive LO frequency may be produced by the frequency synthesizer 240, which may be buffered or amplified by an amplifier (not shown) before being mixed with the RF signals in the mixer 234. Separate frequency synthesizers may be used for the TX path 218 and the RX path 222.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC (e.g., the AGC manager 106), which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated with the memory 214 or being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Multi-Connectivity Automatic Gain Control

Aspects of the present disclosure provide techniques for multi-connectivity AGC, which may enable reduced power consumption and/or lower complexity for receivers.

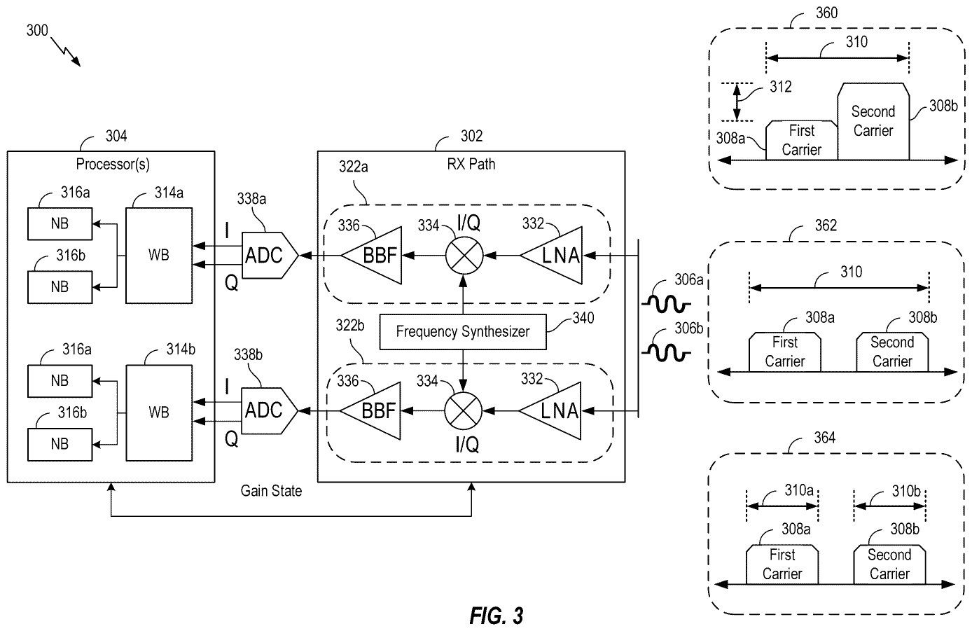

FIG. 3 depicts an example receiver architecture 300 that employs multi-connectivity AGC, for example, in various frequency band scenarios. The receiver architecture 300 may be included in or implemented by a wireless communications device, such as the first wireless device 102 of FIGS. 1 and 2. The receiver architecture 300 may include a receive path 302 and one or more processors (hereinafter “the processor 304”). The processor 304 may be an example of the processor 212 and/or the modem 210 of FIG. 2. In certain aspects, the AGC manager 106 of FIGS. 1 and 2 may be included in or performed by the processor 304. The processor 304 may be coupled to the receive path 302. In certain cases, the processor 304 may be coupled to memory, such as the memory 214 of FIG. 2.

The receive path 302 may be configured to receive signaling comprising a first signal 306a and a second signal 306b. In certain aspects, the first signal 306a may be associated with a first RAT (e.g., E-UTRA), and the second signal 306b may be associated with a second RAT (e.g., 5G NR). The first RAT may include a first WWAN, and the second RAT may include a second WWAN. In certain aspects, the first signal 306a may include a first data signal and/or a first set of reference signals (such as a cell-specific reference signal (CRS)), and the second signal 306b may include a second data signal and/or a second set of reference signals (such as a demodulation reference signal (DMRS), a synchronization signal, a tracking reference signal (TRS), a channel state information reference signal (CSI-RS), and/or the like).

The signals for different RATs may be formed using different modulation and coding schemes, different signal sequences (e.g., a Zadoff-Chu sequence), and/or communicated at different transmission time intervals (which may or may not be time synchronized with each other). As an example, the CRS for E-UTRA systems may be communicated in every slot or subframe. The DMRS for 5G NR systems may be communicated along with a synchronization signal and/or a data signal. The synchronization signal may be communicated according to a periodicity associated with a synchronization signaling burst (e.g., 5 milliseconds (ms), 10 ms, 20 ms, 40 ms, 80 ms, 160 ms, or the like). The TRS may be communicated periodically and/or aperiodically. Accordingly, the processor 304 may be configured to identify certain metrics (e.g., signal strengths) associated with various received signals corresponding to multiple RATs and adjust a gain state based on the metric associated with the received signals as further described herein.

In certain cases, the first signal 306a and the second signal 306b may be communicated in an intra-band scenario or an inter-band scenario. As an example, the first signal 306a may be in a first frequency carrier (hereinafter “the first carrier 308a”), and the second signal may be in second frequency carrier (hereinafter “the second carrier 380b”). A frequency carrier may be a frequency range of an operating frequency band specified for wireless communications, such as the operating frequency band of 5G NR systems and/or E-UTRA systems (e.g., n41 and/or b41).

As a first intra-band example 360, the first carrier 308a and the second carrier 308 may form a contiguous occupied bandwidth in one or more operating frequency bands (hereinafter “the operating frequency band 310”). For example, the first carrier 308a may be arranged adjacent to the second carrier 308b in the operating frequency band 310. In certain cases, the operating frequency band 310 may correspond to the operating frequency band(s) of multiple RATs, such as n41 and b41. As an example, the operating frequency band 310 may include a first frequency band associated with a first RAT and a second frequency band associated with a second RAT. The first frequency band may be overlapping with the second frequency band in the frequency domain, such as n41 and b41. The first carrier 380a may be arranged in the first frequency band (e.g., b41), and the second carrier 308b may be arranged in the second frequency band (e.g., n41).

In certain aspects, the first signal 306a and the second signal 306b may have received signal powers within a threshold difference 312 of each other, such as 6 dB. In certain aspects, the first signal 306a and the second signal 306b may be expected to be output by co-located base station(s) (or radio heads) at transmit powers within the threshold difference 312 of each other

As a second intra-band example 362, the first carrier 308a and the second carrier 308b may be non-contiguous in the operating frequency band 310 (e.g., including overlapping frequency bands associated with multiple RATs). For example, a guard band may be effectively arranged between the first carrier 308a and the second carrier 308b in the frequency domain.

As an inter-band example 364, the first carrier 308a may be arranged in a first operating frequency band 310a in the frequency domain, and the second carrier 308b may be arranged in a second operating frequency band 310b in the frequency domain. The second operating frequency band 310b may not overlap (be non-overlapping) with the first operating frequency band 310a in the frequency domain.

The receive path 302 may be an example of the RX path 222 of FIG. 2. The receive path 302 may include one or more components, such as an amplifier, a mixer, and/or baseband filter, as further described herein. The components may be configured to operate across the occupied bandwidth of the first carrier 308a and the second carrier 308b. In certain aspects, the receive path 302 may include a first receive chain 322a and a second receive chain 322b. The first receive chain 322a may be or include a primary receive chain, and the second receive chain 322b may be or include a diversity receive chain with respect to the primary receive chain. The primary receive chain and the diversity receive chain may be coupled to the same antenna or different antennas, such as the antennas 220 of FIG. 2. In certain cases, the receive path may include a single receive chain (e.g., the first receive chain) without a diversity receive chain (e.g., the second receive chain).

The first receive chain 322a may include one or more amplifiers (hereinafter “the amplifier 332”), one or mixers (hereinafter “the mixer 334”), and one or more filters (hereinafter “the filter 336”), for example, as described herein with respect to FIG. 2. The amplifier 332 may be or include a low noise amplifier, such as the LNA 232 of FIG. 2. The mixer 334 may be an example of the mixer 234 of FIG. 2. The filter 336 may be an example of the BBF 236 of FIG. 2. A frequency synthesizer 340 may be coupled to and feed one or more LO signals to the mixer 334. The frequency synthesizer 340 may be an example of the frequency synthesizer 240 of FIG. 2.

In certain aspects, the second receive chain 322b may have the same general circuit architecture as the first receive chain 322a. As an example, the second receive chain 322b may include the amplifier 332, the mixer 334, and the filter 336. The frequency synthesizer 340 may feed the one or more LO signals to the mixer 334 of the first receive chain 322a and the mixer 334 of the second receive chain 322b. For example, the same frequency synthesizer may be coupled to the first receive chain 322a and the second receive chain 322b. In certain aspects, the LO signal(s) (fed to the mixers 334 of the first receive chain 322a and the second receive chain 322b) may be formed to be between the first carrier and the second carrier in the frequency domain. The LO signal(s) may have a frequency that is between the first carrier 308a and the second carrier 308b. In certain cases, each of the first receive chain 322a and the second receive chain 322b may be coupled to a separate frequency synthesizer. Note that the circuit architecture of the first receive chain 322a and the second receive chain 322b are example architectures, and aspects of the present disclosure may apply to any other suitable receive chain architecture.

The receive path 302 may convert the first signal 306a and the second signal 306b to baseband signal(s) as described herein with respect to FIG. 2. In certain aspects, the first receive chain 322a and the second receive chain 322b may be configured to process the received (multi-connectivity) signaling independently (or separately) of each other across the occupied bandwidth of the first carrier 308a and the second carrier 308b. The first receive chain 322a may be configured to receive signaling (which may comprise the first signal 306a and/or the second signal 306b) in a multi-connectivity mode (e.g., EN-DC), and the second receive chain 322b may be configured to receive the signaling in the multi-connectivity mode. Each of the first receive chain 322a and the second receive chain 322b may perform wideband operations with respect to the occupied bandwidth of the first carrier 308a and the second carrier 308b.

As an example, the first receive chain 322a may filter and/or downconvert the signaling to extract a first set of baseband signals (e.g., including a first baseband signal associated with the first signal 306a and/or a second baseband signal associated with the second signal 306b); and the second receive chain 322b may filter and/or downconvert the signaling to extract a second set of baseband signals (e.g., including the first baseband signal associated with the first signal 306a and/or the second baseband signal associated with the second signal 306b). In certain cases, the filtering and/or downconversion operations may be applied independently at the first receive chain 322a and the second receive chain 322b, for example, due to the first signal 306a and/or the second signal 306b having one or more different properties (e.g., carrier or channel bandwidths, carrier frequencies, or the like). As further described herein, the first receive chain 322a and the second receive chain 322b may apply a set of gains to the respective set of components of the receive chain, where the set of gains may be derived based on a common metric associated with the first signal 306a and the second signal 306b.

The receive path 302 may feed the baseband signal(s) to one or more ADCs, which may digitize the baseband signals to digital samples. As an example, the first receive chain 322a may feed the first set of baseband signals to a first ADC 338a, and the second receive chain 322b may feed the second set of baseband signals to a second ADC 338b. Each of the first ADC 338a and the second ADC 338b may be an example of the ADC 238 of FIG. 2. The ADC 338a, 338b may feed the digital samples to the processor 304, which may perform digital signaling processing operations on the digital samples.

The processor 304 may perform wideband processing operations 314a, 314b and/or narrowband processing operations 316a, 316b. In certain cases, the processor 304 may perform separate signal processing operations on the baseband signals obtained from the first receive chain 322a and the second receive chain 322b. The wideband processing operations 314a, 314b may include certain operations performed across the occupied frequency bandwidth (of the first carrier 308a and the second carrier 308b) associated with the first signal 306a and the second signal 306b. The wideband processing operations may include, for example, decimation of received downlink signal, impairment mitigations, etc. The narrowband processing operations 316a, 316b may include first narrowband processing operations 316a associated with the first carrier 308a of the first signal 306a and second narrowband processing operations 316b associated with the second carrier 308b of the second signal 306b. The narrowband processing operations 316a, 316b may include, for example, symbol detection, symbol demodulation, symbol decoding, narrowband channel equalization, narrowband channel decoding, narrowband channel estimation, narrowband interference cancellation, and/or the like. The narrowband processing operations 316a, 316b may include determination of certain metrics associated with the first signal 306a and the second signal 306b, such as determining the signal strengths of the first signal 306a and the second signal 306b.

The processor 304 may perform multi-connectivity AGC. The processor 304 may determine a gain state applied to certain component(s) of the receive path 302 for multi-connectivity AGC based on the first signal 306a and the second signal 306b. The processor 304 may perform AGC on the receive path 302 using a gain level (or gain state) selected for the first receive chain 322a and the second receive chain 322b based at least in part on a maximum value among one or more first signal strengths associated with the first signal 306a and one or more second signal strengths associated with the second signal 306b. The multi-connectivity AGC may enable the receiver architecture 300 to reduce power consumption, for example, due to multi-connectivity signaling being received via a single receive path, such as the receive path 302 of FIG. 3. The gain state may be or include a set of gains applied to the component(s), such as the filter 336, the mixer 334, and/or the amplifier 332 of the first receive chain 322a and/or the second receive chain 322b. As an example, the set of gains may include a first gain applied to the filter 336, a second gain applied to the mixer 334, and/or a third gain applied to the amplifier 332. The set of gains may include a first set of gains for a first set of components of the first receive chain 322a and/or a second set of gains for a second set of components of the second receive chain 322b.

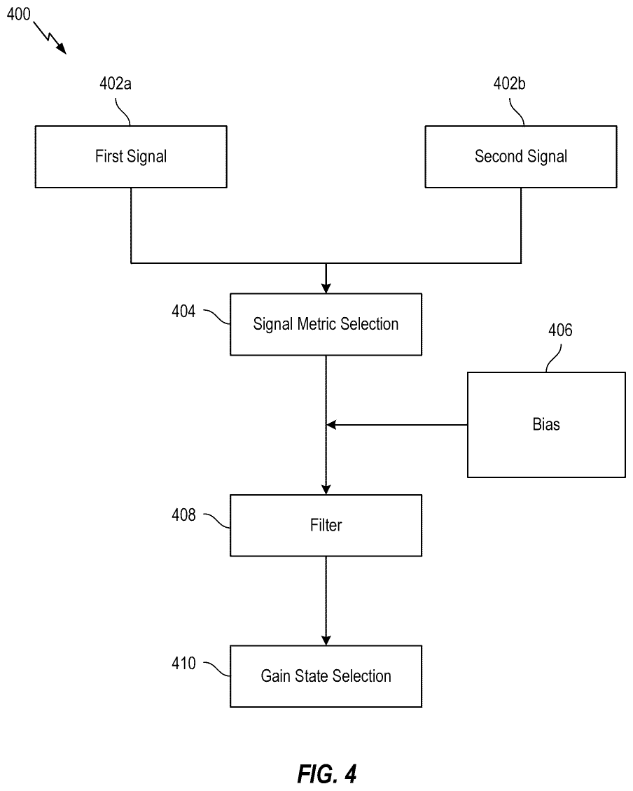

The processor 304 may determine the gain state (or the set of gains) applied to the component(s) based at least in part on one or more first metrics associated with the first signal 306a and one or more second metrics associated with the second signal 306b, for example, as further described herein with respect to FIG. 4. The processor 304 may determine the gain state based at least in part on a comparison between the metrics associated with the first signal 306a and the second signal 306b. For example, the processor 304 may determine a maximum signal strength among the first signal 306a and the second signal 306b, and the processor 304 may determine the gain state based on the maximum signal strength. The processor 304 may send, to the receive path 302, an indication of the gain state to use for the next transmission time interval.

FIG. 4 depicts example operations 400 for multi-connectivity AGC. In certain cases, the operations 400 may be performed by a wireless communications device, such as the first wireless device of FIGS. 1 and 2. The wireless device may include a receiver architecture, such as the receiver architecture 300 of FIG. 3. In certain aspects, the operations 400 may be performed by a processor coupled to a receive path, for example, as described herein with respect to FIG. 3. In certain aspects, the operations 400 may be performed by the AGC manager 106 of FIGS. 1 and 2.

The operations 400 may optionally begin at blocks 402a, 402b, where the wireless device may obtain multi-connectivity signaling that includes a first signal and a second signal. The wireless device may obtain the multi-connectivity signaling via a single receive path, for example, as described herein with respect to FIG. 4. As described herein with respect to FIG. 3, the first signal may be associated with a first RAT (e.g., an E-UTRA system), and the second signal may be associated with a second RAT (e.g., a 5G NR system). The first signal may include a first data signal and/or a first set of reference signals (e.g., a CRS), and the second signal may include a second data signal and/or a second set of reference signals (e.g., a DMRS, synchronization signal, a TRS, and/or the like). The synchronization signal may be or include a primary synchronization signal (PSS), a secondary synchronization signal (SSS), and/or the like. In certain aspects, the wireless device may obtain the first signal in a first transmission time internal (e.g., a slot) and the second signal in a second transmission time interval (e.g., a slot).

At block 404, the wireless device may perform signal metric selection among a plurality of signal metrics associated with the first signal and the second signal. The wireless device may select a signal metric associated with the first signal and the second signal. The signal metric may be a common metric associated with the first signal and the second signal. The signal metric may be selected among a plurality of metrics associated with the first signal and the second signal. As an example, the metrics may include signal strengths associated with the first signal and/or the second signal. The signal strength may be or include a received signal strength indicator (RSSI), a reference signal received power (RSRP), and/or the like. The signal strengths may include a first signal strength associated with the first data signal, a second signal strength associated with the first set of reference signals, a third signal strength associated with the second data signal, and/or a fourth signal strength associated with the second set of reference signals. As an example, the wireless device may select a maximum value (e.g., highest value) among the signal strengths as the signal metric.

In certain cases, the wireless device may determine a first signal strength associated with the first signal based at least in part on the first set of reference signals and the first data signal (for example, the maximum signal strength among the first set of reference signals and the first data signal). The wireless device may determine a second signal strength based at least in part on the second set of reference signals and the second data signal (for example, the maximum signal strength among the second set of reference signals and the second data signal). The wireless device may determine the maximum signal strength among the first signal strength and the second signal strength as the signal metric.

At block 406, the wireless device may optionally apply a bias to adjust (e.g., increase or decrease) the signal metric, such as the maximum signal strength, determined at block 404. The bias may allow the wireless device to improve the signal quality of the received signals across the occupied bandwidth of the signals. For example, the bias may allow the wireless device to effectively boost the signaling on the edges of the occupied bandwidth. In certain cases, the wireless device may reduce the signal metric (e.g., the maximum signal strength) by the bias. The bias may be equal to the difference between a first signal strength associated with data signals and a second signal strength associated with reference signals. For example, the bias may be equal to the difference between a first signal strength and a second signal strength, where the first signal strength is a maximum signal strength (e.g., highest signal strength) among the first data signal and the second data signal, and the second signal strength is a minimum signal strength (e.g., lowest signal strength) among the first set of reference signals and the second set of reference signals.

The bias may be applied based on a first signal strength associated with the first data signal and the second data signal satisfying a threshold relative to a second signal strength associated with the first set of reference signals and the second set of reference signals. As an example, if a maximum signal strength among the first data signal and the second data signal is greater than a minimum signal strength among the reference signals (e.g., the first set of reference signals and the second set of reference signals), the wireless device may apply the bias to the signal metric (e.g., the maximum signal strength) determined at block 404. Otherwise, the wireless device may refrain from applying the bias, for example, when the maximum signal strength of the data signals is less than the minimum signal strength of the reference signals.

At block 408, the wireless device may apply a filter to the signal metric determined at block 404 or at block 406. As an example, the wireless device may apply the filter to the signal metric based at least in part on the previous output value of the filter (e.g., the previous filtered signal metric). The filter may be or include an infinite impulse response (IIR) filter, such as a single pole IIR filter. For example, the filtered signal metric (y[n]) may be determined according to the following expression:

$$y [ n ] = ( 1 - α ) x [ n ] + α y [ n - 1 ] ,$$

where x[n] is the signal metric determined at block 404 or at block 406, y[n−1] is the previous output value of the filter, and α is a scaling factor that sets a level of decay associated with the filter. The wireless device may apply the filter to smooth or dampen the signal metric (e.g., the signal strength) used for a gain state selection. The filter may effectively apply a moving average to the signal metric over a time window to suppress potential glitches or surges in the signal metric.

At block 410, the wireless device may select a gain state (among a plurality of gain states) to apply to component(s) of the receive path based on the filtered signal metric (e.g., the signal strength). As discussed herein, the gain state may include a set of gains applied to the component(s) of the receive path. Each of the gain states may correspond to a separate set of gains applied to the component(s). As an example, a first gain state may correspond to a first set of gains, and a second gain state may correspond to a second set of gains. The first set of gains may be different from the second set of gains. The wireless device may apply the gain state for the next transmission time interval (e.g., the next slot) associated with the signaling. In certain cases, the wireless device may adjust the set of gains applied to the component(s) based on the gain state selection. For example, the previous gain state selection may be a different gain state than the gain state selected for the next transmission time interval. The wireless device may repeat the operations 400 at a subsequent transmission time interval, such as the next slot. Accordingly, the multi-connectivity AGC may enable reduced power consumption, for example, due to a single receive path being used to receive the first signal and the second signal.

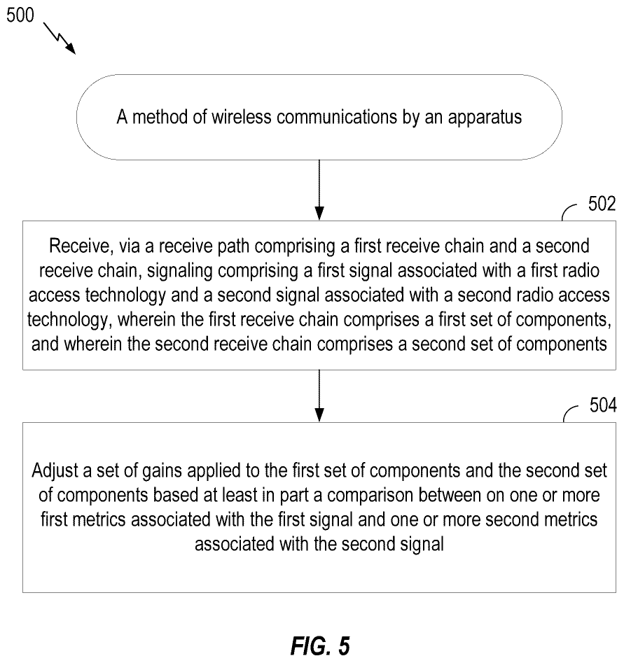

FIG. 5 depicts example operations 500 for wireless communications by an apparatus. The operations 500 may be performed, for example, by a wireless device (e.g., the first wireless device 102 in the wireless communications system 100). In certain aspects, the wireless device may include a receiver architecture as described herein with respect to FIG. 3. The operations 500 may be implemented as software components that are executed and run on one or more processors (e.g., the modem 210 and/or the processor 212 of FIG. 2). Further, the transmission and/or reception of signals by the wireless device in the operations 500 may be enabled, for example, by one or more antennas (e.g., the antenna 220 of FIG. 2). In certain aspects, the transmission and/or reception of signals by the wireless device may be implemented via a bus interface of one or more processors (e.g., the modem 210 and/or the processor 212 of FIG. 2) obtaining and/or outputting signals for reception or transmission.

The operations 500 may optionally begin, at block 502, where the wireless device may receive, via a receive path (e.g., the receive path 302 of FIG. 3) comprising a first receive chain (e.g., the first receive chain 322a) and a second receive chain (e.g., the second receive chain 322b), signaling comprising a first signal associated with a first radio access technology and a second signal associated with a second radio access technology, wherein the first receive chain comprises a first set of components, and wherein the second receive chain comprises a second set of components, for example, as described herein with respect to FIGS. 3 and 4. In certain aspects, the first signal is in a first frequency carrier, and the second signal is in a second frequency carrier.

At block 504, the wireless device may adjust a set of gains applied to the first set of components and the second set of components based at least in part a comparison between on one or more first metrics associated with the first signal and one or more second metrics associated with the second signal, for example, as described herein with respect to FIGS. 3 and 4.

In certain aspects, receiving the signaling at block 502 comprises receiving the signaling, in a multi-connectivity mode, via the first receive chain and the second receive chain; the first radio access technology includes a first wireless wide area network; and the second radio access technology includes a second wireless wide area network.

In certain aspects, the multi-connectivity mode comprises Evolved-Universal Terrestrial Radio Access-New Radio Dual Connectivity (EN-DC).

In certain aspects, the one or more first metrics includes a first signal strength; and the one or more second metrics includes a second signal strength.

In certain aspects, the first signal includes a first set of reference signals; the second signal includes a second set of reference signals; the first signal strength is based at least in part on the first set of reference signals; and the second signal strength is based at least in part on the second set of reference signals.

In certain aspects, the first signal includes a first data signal; the second signal includes a second data signal; the first signal strength is based at least in part on the first set of reference signals and the first data signal; and the second signal strength is based at least in part on the second set of reference signals and the second data signal.

In certain aspects, the first set of reference signals includes a cell specific reference signal; and the second set of reference signals includes one or more of a demodulation reference signal, a synchronization signal, or a tracking reference signal.

In certain aspects, adjusting the set of gains at block 504 comprises: identifying a maximum value among the one or more first metrics associated with the first data signal and the one or more second metrics associated with the second data signal; and adjusting the set of gains based at least in part on the maximum value.

In certain aspects, adjusting the set of gains at block 504 comprises: identifying a minimum value among the one or more first metrics associated with the first set of reference signals and the one or more second metrics associated with the second set of reference signals; and adjusting the set of gains based at least in part on the maximum value and the minimum value.

In certain aspects, adjusting the set of gains at block 504 comprises: applying a bias to one or more of the first data signal or the second data signal, wherein the bias corresponds to a difference between the maximum value and the minimum value; and adjusting the set of gains based at least in part on one or more of the biased first data signal or the biased second data signal.

In certain aspects, the first receive chain comprises a first set of mixers; the second receive chain comprises a second set of mixers. In certain aspects, the operations 500 further comprise feeding, via a frequency synthesizer, one or more local oscillator signals to the first set of mixers and the second set of mixers.

In certain aspects, the first signal is in a first frequency carrier; the second signal is in a second frequency carrier; and the one or more local oscillator signals are arranged between the first frequency carrier and the second frequency carrier in a frequency domain.

In certain aspects, the first frequency carrier is in a first frequency band, the second frequency carrier is in a second frequency band, and the first frequency band is overlapping with the second frequency band in the frequency domain.

In certain aspects, the first frequency carrier is in a first frequency band, the second frequency carrier is in a second frequency band, and the first frequency band is non-overlapping with the second frequency band in the frequency domain.

In certain aspects, adjusting the set of gains at block 504 comprises adjusting the set of gains for a transmission time interval associated with the signaling.

Note that FIGS. 3-5 are described herein with respect to multi-connectivity signaling to facilitate an understanding of multi-connectivity AGC. Aspects of the present disclosure may be applied to multi-connectivity signaling that comprises a plurality of signals associated with various RATs, such as any future RAT. Aspects of the present disclosure may be applied to any of various wireless communication devices that may perform multi-connectivity AGC described herein.

### Example Communications Device

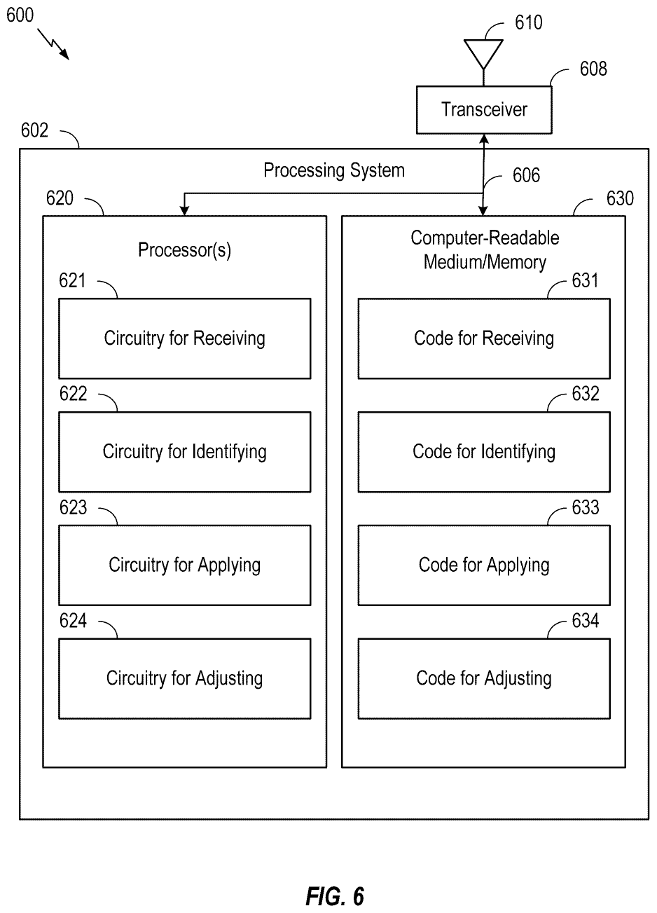

FIG. 6 depicts aspects of an example communications device 600. In some aspects, communications device 600 is a wireless communication device, such as the first wireless device 102 described above with respect to FIGS. 1 and 2.

The communications device 600 includes a processing system 602 coupled to a transceiver 608 (e.g., a transmitter and/or a receiver). The transceiver 608 is configured to transmit and receive signals for the communications device 600 via an antenna 610, such as the various signals described herein. The processing system 602 may be configured to perform processing functions for the communications device 600, including processing signals received and/or to be transmitted by the communications device 600.

The processing system 602 includes one or more processors 620. In various aspects, the one or more processors 620 may be representative of any of the modem 210 and/or the processor 212, as described with respect to FIG. 2. The one or more processors 620 are coupled to a computer-readable medium/memory 630 via a bus 606. In certain aspects, the computer-readable medium/memory 630 is configured to store instructions (e.g., computer-executable code) that when executed by the one or more processors 620, cause the one or more processors 620 to perform the operations 400 described with respect to FIG. 4, the operations 500 described with respect to FIG. 5, or any aspect related to the operations described herein. Note that reference to a processor performing a function of communications device 600 may include one or more processors performing that function of communications device 600. Reference to one or more processors performing multiple functions may include any one of the one or more processors performing any one of the multiple functions.

In the depicted example, computer-readable medium/memory 630 stores code (e.g., executable instructions) for receiving 631, code for identifying 632, code for applying 633, code for adjusting 634, or any combination thereof. Processing of the code 631-634 may cause the communications device 600 to perform the operations 400 described with respect to FIG. 4, the operations 500 described with respect to FIG. 5, or any aspect related to operations described herein.

The one or more processors 620 include circuitry configured to implement (e.g., execute) the code stored in the computer-readable medium/memory 630, including circuitry for receiving 621, circuitry for identifying 622, circuitry for applying 623, circuitry for adjusting 624, or any combination thereof. Processing with circuitry 621-624 may cause the communications device 600 to perform the operations 400 described with respect to FIG. 4, the operations 500 described with respect to FIG. 5, or any aspect related to operations described herein.

Various components of the communications device 600 may provide means for performing the operations 400 described with respect to FIG. 4, the operations 500 described with respect to FIG. 5, or any aspect related to operations described herein. For example, means for transmitting, sending or outputting for transmission may include the TX path 218 and/or antenna(s) 220 of the first wireless device 102 illustrated in FIG. 2 and/or transceiver 608 and antenna 610 of the communications device 600 in FIG. 6. Means for receiving or obtaining may include the RX path 222 and/or antenna(s) 220 of the first wireless device illustrated in FIG. 2 and/or transceiver 608 and antenna 610 of the communications device 600 in FIG. 6. Means for identifying, means for applying, and/or means for adjusting may include one or more processors, such as the modem 210 and/or processor 212 depicted in FIG. 2 and/or the processor(s) 620 in FIG. 6.

### Example Aspects

Implementation examples are described in the following numbered clauses:

Aspect 1: An apparatus configured for wireless communications, comprising: a receive path configured to receive signaling comprising a first signal associated with a first radio access technology and a second signal associated with a second radio access technology, wherein the receive path comprises a first receive chain and a second receive chain, wherein the first receive chain comprises a first set of components, and wherein the second receive chain comprises a second set of components; and one or more processors coupled to the receive path, the one or more processors being configured to cause the apparatus to adjust a set of gains applied to the first set of components and the second set of components based at least in part on a comparison between one or more first metrics associated with the first signal and one or more second metrics associated with the second signal.

Aspect 2: The apparatus of Aspect 1, wherein: the first receive chain is configured to receive the signaling in a multi-connectivity mode; the second receive chain is configured to receive the signaling in the multi-connectivity mode; the first radio access technology includes a first wireless wide area network; and the second radio access technology includes a second wireless wide area network.

Aspect 3: The apparatus of Aspect 2, wherein the multi-connectivity mode comprises Evolved-Universal Terrestrial Radio Access-New Radio Dual Connectivity (EN-DC).

Aspect 4: The apparatus according to any of Aspects 1-3, wherein: the one or more first metrics includes a first signal strength; and the one or more second metrics includes a second signal strength.

Aspect 5: The apparatus of Aspect 4, wherein: the first signal includes a first set of reference signals; the second signal includes a second set of reference signals; the first signal strength is based at least in part on the first set of reference signals; and the second signal strength is based at least in part on the second set of reference signals.

Aspect 6: The apparatus of Aspect 5, wherein: the first signal includes a first data signal; the second signal includes a second data signal; the first signal strength is based at least in part on the first set of reference signals and the first data signal; and the second signal strength is based at least in part on the second set of reference signals and the second data signal.

Aspect 7: The apparatus of Aspect 5 or 6, wherein: the first set of reference signals includes a cell specific reference signal; and the second set of reference signals includes one or more of a demodulation reference signal, a synchronization signal, or a tracking reference signal.

Aspect 8: The apparatus of Aspect 6 or 7, wherein to adjust the set of gains, the one or more processors are configured to cause the apparatus to: identify a maximum value among the one or more first metrics associated with the first data signal and the one or more second metrics associated with the second data signal; and adjust the set of gains based at least in part on the maximum value.

Aspect 9: The apparatus of Aspect 8, wherein to adjust the set of gains, the one or more processors are configured to cause the apparatus to: identify a minimum value among the one or more first metrics associated with the first set of reference signals and the one or more second metrics associated with the second set of reference signals; and adjust the set of gains based at least in part on the maximum value and the minimum value.

Aspect 10: The apparatus of Aspect 9, wherein to adjust the set of gains, the one or more processors are configured to cause the apparatus to: apply a bias to one or more of the first data signal or the second data signal, wherein the bias corresponds to a difference between the maximum value and the minimum value; and adjust the set of gains based at least in part on one or more of the biased first data signal or the biased second data signal.

Aspect 11: The apparatus according to any of Aspects 1-10, wherein: the first receive chain comprises a first set of mixers; the second receive chain comprises a second set of mixers; and the apparatus further comprises a frequency synthesizer configured to feed one or more local oscillator signals to the first set of mixers and the second set of mixers.

Aspect 12: The apparatus of Aspect 11, wherein: the first signal is in a first frequency carrier; the second signal is in a second frequency carrier; and the one or more local oscillator signals are arranged between the first frequency carrier and the second frequency carrier in a frequency domain.

Aspect 13: The apparatus of Aspect 12, wherein the first frequency carrier is in a first frequency band, the second frequency carrier is in a second frequency band, and the first frequency band is overlapping with the second frequency band in the frequency domain.

Aspect 14: The apparatus of Aspect 12 or 13, wherein the first frequency carrier is in a first frequency band, the second frequency carrier is in a second frequency band, and the first frequency band is non-overlapping with the second frequency band in the frequency domain.

Aspect 15: The apparatus according to any of Aspects 1-14, wherein to adjust the set of gains, the one or more processors are configured to cause the apparatus to adjust the set of gains for a transmission time interval associated with the signaling.

Aspect 16: The apparatus according to any of Aspects 1-15, wherein: the first set of components comprises one or more of: one or more first amplifiers, one or more first mixers, or one or more first filters; and the second set of components comprises one or more of: one or more second amplifiers, one or more second mixers, or one or more second filters.

Aspect 17: A radio frequency (RF) circuit configured for wireless communications, comprising: a transceiver comprising: a receive path configured to receive, in a multi-connectivity mode, signaling comprising a first signal associated with a first radio access technology and a second signal associated with a second radio access technology, wherein the receive path comprises a first receive chain and a second receive chain, wherein the first receive chain comprises a first set of components including a first set of mixers, and wherein the second receive chain comprises a second set of components including a second set of mixers; and a frequency synthesizer coupled to the first set of mixers and the second set of mixers, wherein the frequency synthesizer is configured to feed one or more local oscillator signals to the first set of mixers and the second set of mixers; and one or more processors coupled to the receive path, the one or more processors being configured to adjust a set of gains applied to the first set of components and the second set of components based at least in part on a comparison between one or more first signal strengths associated with the first signal and one or more second signal strengths associated with the second signal.

Aspect 18: The RF circuit of Aspect 17, wherein to adjust the set of gains, the one or more processors are configured to perform automatic gain control on the receive path using a gain level selected for the first receive chain and the second receive chain based at least in part on a maximum value among the one or more first signal strengths associated with the first signal and the one or more second signal strengths associated with the second signal; the one or more first signal strengths comprise at least one first received signal strength indicator (RSSI) associated with New Radio (NR); and the one or more second signal strengths comprise at least one second RSSI associated with Long Term Evolution (LTE).

Aspect 19: A method of wireless communications, comprising: receiving, via a receive path comprising a first receive chain and a second receive chain, signaling comprising a first signal associated with a first radio access technology and a second signal associated with a second radio access technology, wherein the first receive chain comprises a first set of components, and wherein the second receive chain comprises a second set of components; and adjusting a set of gains applied to the first set of components and the second set of components based at least in part a comparison between on one or more first metrics associated with the first signal and one or more second metrics associated with the second signal.

Aspect 20: The method of Aspect 19, wherein: receiving the signaling comprises receiving the signaling, in a multi-connectivity mode, via the first receive chain and the second receive chain; the first radio access technology includes a first wireless wide area network; and the second radio access technology includes a second wireless wide area network.

Aspect 21: The method of Aspect 20, wherein the multi-connectivity mode comprises Evolved-Universal Terrestrial Radio Access-New Radio Dual Connectivity (EN-DC).

Aspect 22: The method according to any of Aspects 19-21, wherein: the one or more first metrics includes a first signal strength; and the one or more second metrics includes a second signal strength.

Aspect 23: The method of Aspect 22, wherein: the first signal includes a first set of reference signals; the second signal includes a second set of reference signals; the first signal strength is based at least in part on the first set of reference signals; and the second signal strength is based at least in part on the second set of reference signals.

Aspect 24: The method of Aspect 23, wherein: the first signal includes a first data signal; the second signal includes a second data signal; the first signal strength is based at least in part on the first set of reference signals and the first data signal; and the second signal strength is based at least in part on the second set of reference signals and the second data signal.

Aspect 25: The method of Aspect 23 or 24, wherein: the first set of reference signals includes a cell specific reference signal; and the second set of reference signals includes one or more of a demodulation reference signal, a synchronization signal, or a tracking reference signal.

Aspect 26: The method of Aspect 24 or 25, wherein adjusting the set of gains comprises: identifying a maximum value among the one or more first metrics associated with the first data signal and the one or more second metrics associated with the second data signal; and adjusting the set of gains based at least in part on the maximum value.

Aspect 27: The method of Aspect 26, wherein adjusting the set of gains comprises: identifying a minimum value among the one or more first metrics associated with the first set of reference signals and the one or more second metrics associated with the second set of reference signals; and adjusting the set of gains based at least in part on the maximum value and the minimum value.

Aspect 28: The method of Aspect 27, wherein adjusting the set of gains comprises: applying a bias to one or more of the first data signal or the second data signal, wherein the bias corresponds to a difference between the maximum value and the minimum value; and adjusting the set of gains based at least in part on one or more of the biased first data signal or the biased second data signal.

Aspect 29: The method according to any of Aspects 19-28, wherein: the first receive chain comprises a first set of mixers; the second receive chain comprises a second set of mixers; and the method further comprises feeding, via a frequency synthesizer, one or more local oscillator signals to the first set of mixers and the second set of mixers.

Aspect 30: The method of Aspect 29, wherein: the first signal is in a first frequency carrier; the second signal is in a second frequency carrier; and the one or more local oscillator signals are arranged between the first frequency carrier and the second frequency carrier in a frequency domain.

Aspect 31: The method of Aspect 30, wherein the first frequency carrier is in a first frequency band, the second frequency carrier is in a second frequency band, and the first frequency band is overlapping with the second frequency band in the frequency domain.

Aspect 32: The method of Aspect 30 or 31, wherein the first frequency carrier is in a first frequency band, the second frequency carrier is in a second frequency band, and the first frequency band is non-overlapping with the second frequency band in the frequency domain.

Aspect 33: The method according to any of Aspects 19-32, wherein adjusting the set of gains comprises adjusting the set of gains for a transmission time interval associated with the signaling.

Aspect 34: The method according to any of Aspects 19-33, wherein: the first set of components comprises one or more of: one or more first amplifiers, one or more first mixers, or one or more first filters; and the second set of components comprises one or more of: one or more second amplifiers, one or more second mixers, or one or more second filters.

Aspect 35: An apparatus, comprising: a memory; and one or more processors configured to perform a method in accordance with any of Aspects 19-34.

Aspect 36: An apparatus, comprising means for performing a method in accordance with any of Aspects 19-34.

Aspect 37: A non-transitory computer-readable medium comprising computer-executable instructions that, when executed by one or more processors of a processing system, cause the processing system to perform a method in accordance with any of Aspects 19-34.

Aspect 38: A computer program product embodied on a computer-readable storage medium comprising code for performing a method in accordance with any of Aspects 19-34.

Aspect 39: A method of manufacturing an apparatus, comprising: forming an apparatus in accordance with any of Aspects 1-18.

### ADDITIONAL CONSIDERATIONS

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general purpose processor, an artificial intelligence (AI) processor, a digital signal processor (DSP), an ASIC, a field programmable gate array (FPGA) or other programmable logic device (PLD), discrete gate or transistor logic, discrete hardware components, or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), a system in package (SiP), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining and or like. Also, “determining” may include receiving (e.g., receiving information), accessing (e.g., accessing data in a memory) or the like. Also, “determining” may include resolving, selecting, choosing, establishing or the like.

As used herein, “coupled to” and “coupled with” generally encompass direct coupling and indirect coupling (e.g., including intermediary coupled aspects) unless stated otherwise. For example, stating that a processor is coupled to a memory allows for a direct coupling or a coupling via an intermediary aspect, such as a bus.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Reference to an element in the singular is not intended to mean only one unless specifically so stated, but rather “one or more.” The subsequent use of a definite article (e.g., “the” or “said”) with an element (e.g., “the processor”) is not intended to invoke a singular meaning (e.g., “only one”) on the element unless otherwise specifically stated. For example, reference to an element (e.g., “a processor,” “a controller,” “a memory,” “a transceiver,” “an antenna,” “the processor,” “the controller,” “the memory,” “the transceiver,” “the antenna,” etc.), unless otherwise specifically stated, should be understood to refer to one or more elements (e.g., “one or more processors,” “one or more controllers,” “one or more memories,” “one or more transceivers,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more. All structural and functional equivalents to the elements of the various aspects described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims.

1. An apparatus configured for wireless communications, comprising:
a receive path configured to receive signaling comprising a first signal associated with a first radio access technology and a second signal associated with a second radio access technology, wherein the receive path comprises a first receive chain and a second receive chain, wherein the first receive chain comprises a first set of components, and wherein the second receive chain comprises a second set of components; and
one or more processors coupled to the receive path, the one or more processors being configured to cause the apparatus to adjust a set of gains applied to the first set of components and the second set of components based at least in part on a comparison between one or more first metrics associated with the first signal and one or more second metrics associated with the second signal.

2. The apparatus of claim 1, wherein:
the first receive chain is configured to receive the signaling in a multi-connectivity mode;
the second receive chain is configured to receive the signaling in the multi-connectivity mode;
the first radio access technology includes a first wireless wide area network; and
the second radio access technology includes a second wireless wide area network.

3. The apparatus of claim 2, wherein the multi-connectivity mode comprises Evolved-Universal Terrestrial Radio Access-New Radio Dual Connectivity (EN-DC).

4. The apparatus of claim 1, wherein:
the one or more first metrics includes a first signal strength; and
the one or more second metrics includes a second signal strength.

5. The apparatus of claim 4, wherein:
the first signal includes a first set of reference signals;
the second signal includes a second set of reference signals;
the first signal strength is based at least in part on the first set of reference signals; and
the second signal strength is based at least in part on the second set of reference signals.

6. The apparatus of claim 5, wherein:
the first signal includes a first data signal;
the second signal includes a second data signal;
the first signal strength is based at least in part on the first set of reference signals and the first data signal; and
the second signal strength is based at least in part on the second set of reference signals and the second data signal.

7. The apparatus of claim 5, wherein:
the first set of reference signals includes a cell specific reference signal; and
the second set of reference signals includes one or more of a demodulation reference signal, a synchronization signal, or a tracking reference signal.

8. The apparatus of claim 6, wherein to adjust the set of gains, the one or more processors are configured to cause the apparatus to:
identify a maximum value among the one or more first metrics associated with the first data signal and the one or more second metrics associated with the second data signal; and
adjust the set of gains based at least in part on the maximum value.

9. The apparatus of claim 8, wherein to adjust the set of gains, the one or more processors are configured to cause the apparatus to:
identify a minimum value among the one or more first metrics associated with the first set of reference signals and the one or more second metrics associated with the second set of reference signals; and
adjust the set of gains based at least in part on the maximum value and the minimum value.

10. The apparatus of claim 9, wherein to adjust the set of gains, the one or more processors are configured to cause the apparatus to:
apply a bias to one or more of the first data signal or the second data signal, wherein the bias corresponds to a difference between the maximum value and the minimum value; and
adjust the set of gains based at least in part on one or more of the biased first data signal or the biased second data signal.

11. The apparatus of claim 1, wherein:
the first receive chain comprises a first set of mixers;
the second receive chain comprises a second set of mixers; and
the apparatus further comprises a frequency synthesizer configured to feed one or more local oscillator signals to the first set of mixers and the second set of mixers.

12. The apparatus of claim 11, wherein:
the first signal is in a first frequency carrier;
the second signal is in a second frequency carrier; and
the one or more local oscillator signals are arranged between the first frequency carrier and the second frequency carrier in a frequency domain.

13. The apparatus of claim 12, wherein the first frequency carrier is in a first frequency band, the second frequency carrier is in a second frequency band, and the first frequency band is overlapping with the second frequency band in the frequency domain.

14. The apparatus of claim 12, wherein the first frequency carrier is in a first frequency band, the second frequency carrier is in a second frequency band, and the first frequency band is non-overlapping with the second frequency band in the frequency domain.

15. The apparatus of claim 1, wherein to adjust the set of gains, the one or more processors are configured to cause the apparatus to adjust the set of gains for a transmission time interval associated with the signaling.

16. The apparatus of claim 1, wherein:
the first set of components comprises one or more of: one or more first amplifiers, one or more first mixers, or one or more first filters; and
the second set of components comprises one or more of: one or more second amplifiers, one or more second mixers, or one or more second filters.

17. A radio frequency (RF) circuit configured for wireless communications, comprising:
a transceiver comprising:
a receive path configured to receive, in a multi-connectivity mode, signaling comprising a first signal associated with a first radio access technology and a second signal associated with a second radio access technology, wherein the receive path comprises a first receive chain and a second receive chain, wherein the first receive chain comprises a first set of components including a first set of mixers, and wherein the second receive chain comprises a second set of components including a second set of mixers; and
a frequency synthesizer coupled to the first set of mixers and the second set of mixers, wherein the frequency synthesizer is configured to feed one or more local oscillator signals to the first set of mixers and the second set of mixers; and
one or more processors coupled to the receive path, the one or more processors being configured to adjust a set of gains applied to the first set of components and the second set of components based at least in part on a comparison between one or more first signal strengths associated with the first signal and one or more second signal strengths associated with the second signal.

18. The RF circuit of claim 17, wherein
to adjust the set of gains, the one or more processors are configured to perform automatic gain control on the receive path using a gain level selected for the first receive chain and the second receive chain based at least in part on a maximum value among the one or more first signal strengths associated with the first signal and the one or more second signal strengths associated with the second signal;
the one or more first signal strengths comprise at least one first received signal strength indicator (RSSI) associated with New Radio (NR); and
the one or more second signal strengths comprise at least one second RSSI associated with Long Term Evolution (LTE).

19. A method of wireless communications, comprising:
receiving, via a receive path comprising a first receive chain and a second receive chain, signaling comprising a first signal associated with a first radio access technology and a second signal associated with a second radio access technology, wherein the first receive chain comprises a first set of components, and wherein the second receive chain comprises a second set of components; and
adjusting a set of gains applied to the first set of components and the second set of components based at least in part a comparison between on one or more first metrics associated with the first signal and one or more second metrics associated with the second signal.

20. The method of claim 19, wherein:
receiving the signaling comprises receiving the signaling, in a multi-connectivity mode, via the first receive chain and the second receive chain;
the first radio access technology includes a first wireless wide area network; and
the second radio access technology includes a second wireless wide area network.
